(19) United States
(12) Patent Application Publication
(10) Pub. No.: US 2015/0216066 A1
(43) Pub. Date: Jul. 30, 2015

(54) INTEGRATED CIRCUIT PACKAGE HAVING IMPROVED COPLANARITY

(71) Applicant: Nvidia Corporation, Santa Clara, CA (US)

(72) Inventor: Leilei Zhang, Santa Clara, CA (US)

(73) Assignee: Nvidia Corporation, Santa Clara, CA (US)

(21) Appl. No.: 14/166,682

(22) Filed: Jan. 28, 2014

(51) Int. Cl. H05K 7/02; H05K 3/34; B23K 1/00; H05K 1/11

(52) U.S. Cl. CPC H05K 7/02; H05K 1/111; H05K 3/3436; B23K 1/0016; H05K 2201/068; B23K 2001/12

(57) ABSTRACT

One aspect of the present disclosure provides an IC package that includes a printed circuit board (PCB) having a first material layer located thereon. The first material layer has bond pads located therein that form a contact array defined by a perimeter. A second material layer is located at or adjacent an outer edge of the PCB. The second material layer is located outside the perimeter of the contact array and has a higher coefficient of thermal expansion (CTE) value and a greater thickness than the first material layer.

### TECHNICAL FIELD

This application is directed to an integrated circuit package.

### BACKGROUND

As the form factor for electronic devices, such as cell phones or portable tablets, has become more compact, performance demands for those same electronic devices has increased. Integrated circuit (IC) manufacturers have sought different ways to achieve both of these demands. One way in which IC manufacturers have met performance demand requirements is through the implementation of package-on-package or POP, IC packages. POP packages typically include expanded memory circuits in which memory chips are vertically and directly connected to an underlying integrated processor through solder balls. This has provided more memory capacity for the ever growing performance demands for the above-mentioned electronic devices. However, as performance demands have continued to grow, manufacturers have sought additional ways to expand processing and memory capability while adhering to the “thin” form factor that consumers have grown to expect in such devices. To achieve this, they have increased the size of the footprint (i.e., length/width dimensions) of the underlying printed circuit board (PCB) to which the integrated processor is connected, while keeping the height reduced as much as possible.

### SUMMARY

One aspect of the present disclosure provides an IC package comprising a printed circuit board (PCB) having a first material layer located thereon. The first material layer has bond pads located therein that form a contact array defined by a perimeter. A second material layer is located at or adjacent an outer edge of the PCB. The second material layer is located outside the perimeter of the contact array and has a higher coefficient of thermal expansion (CTE) value and a greater thickness than the first material layer.

Another embodiment is directed to an IC POP device. This embodiment comprises a printed circuit board (PCB) having a first material layer located thereon. The first material layer has bond pads located therein that form a contact array defined by a perimeter. An integrated processor is electrically coupled to the PCB through the contact array. A second material layer is located at or adjacent an outer edge of the PCB and outside the perimeter of the contact array. The second material layer has a higher coefficient of thermal expansion (CTE) value and a greater thickness than the first material layer. Contact openings are located in the second material layer at or adjacent the edge of the PCB and outside the perimeter of the contact array. A packaged IC device is located over the PCB and is electrically connected to the PCB by contacts located in the contact openings of the second material layer.

Another embodiment provides a method of manufacturing an integrated circuit (IC) package. The method comprises forming a bond pad array on a printed circuit board (PCB), forming a first material layer over the bond pad array and forming bond pad openings therein to expose portions of the bond pad array to form a contact array having a perimeter, and forming a second material layer at or adjacent an outer edge of the PCB. The second material layer is located outside of the perimeter of the contact array and has a higher coefficient of thermal expansion (CTE) value and a greater thickness than the first material layer.

### BRIEF DESCRIPTION

Reference is now made to the following descriptions taken in conjunction with the accompanying drawings, in which:

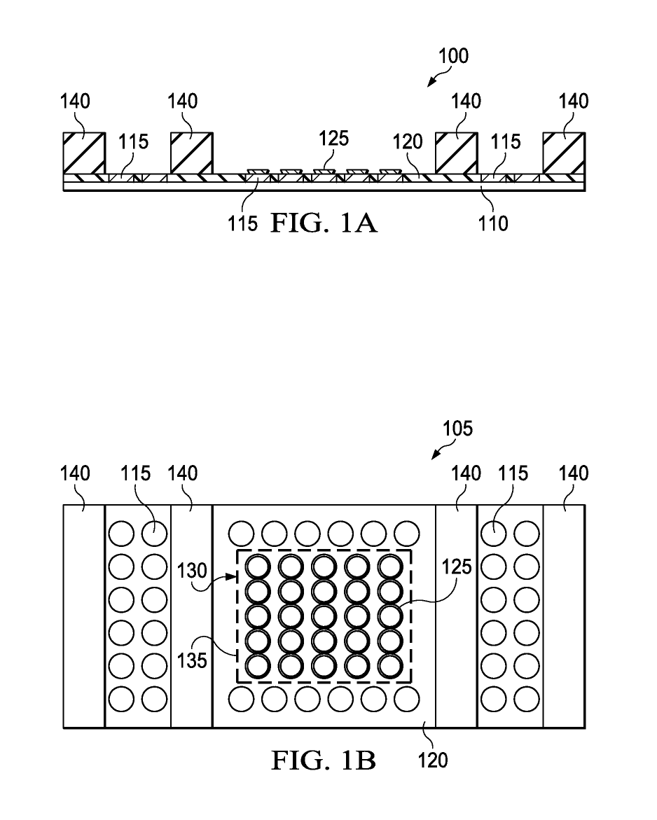

FIG. 1A illustrates a general, schematic side view of one embodiment of an IC device as provided herein;

FIG. 1B illustrates a general, schematic overhead view of the embodiments of FIG. 1A;

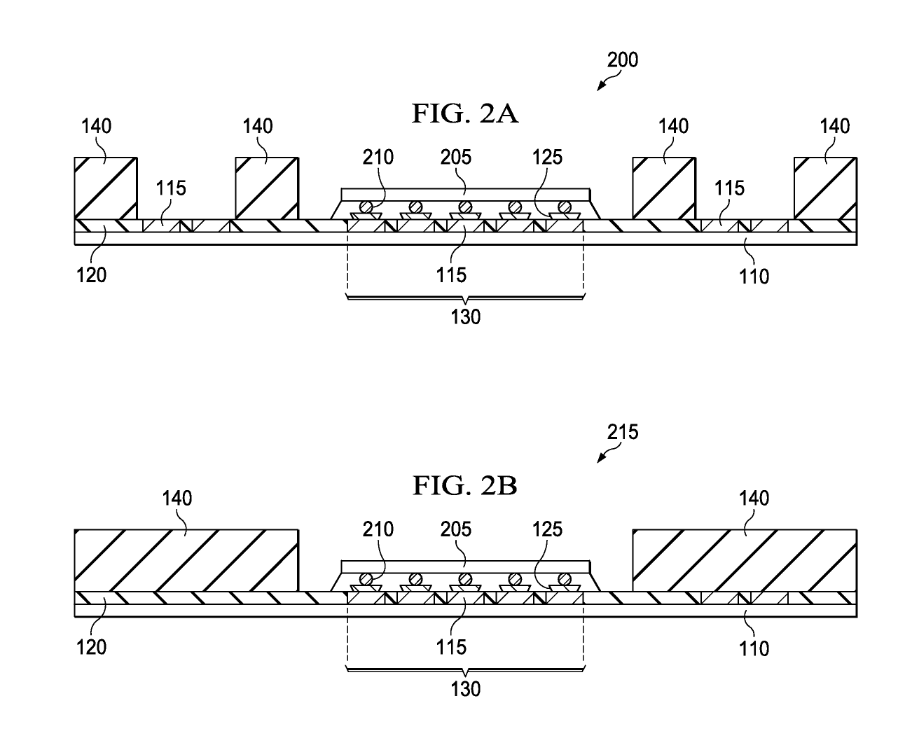

FIG. 2A illustrates another embodiments of the IC device as provided herein that further includes an IC device electrically connected to the PCB by the contact array and that may be implemented in a IC POP device;

FIG. 2B illustrates an embodiment of the IC device as provided herein where the second material layer does not have contact openings formed therein; and

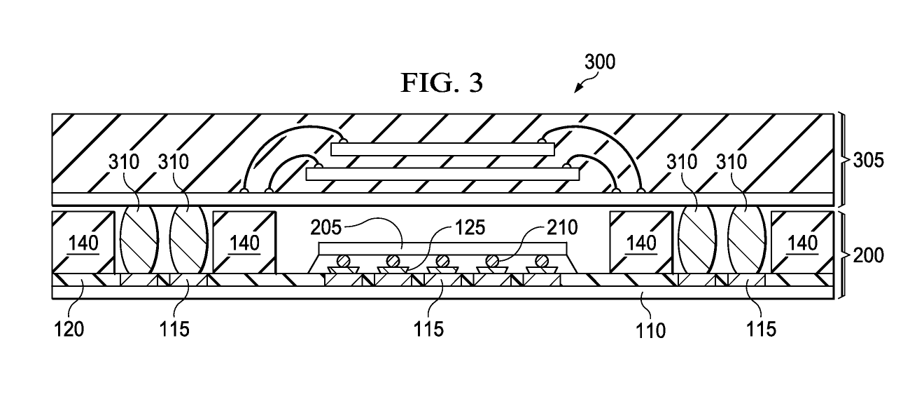

FIG. 3 illustrates an IC POP device in which the embodiment of FIG. 2A is implemented.

### DETAILED DESCRIPTION

Embodiments of the present disclosure provide a thin IC device having larger width/length dimension with improved coplanarity, which have extended from 12 mm to 17 mm with a reduction in thickness from 1.5 mm to 1 mm. As discussed above, manufacturers have sought additional ways to expand processing and memory capability while adhering to a “thin” form factor. To achieve this, they have increased the size of the footprint (i.e., length/width dimensions) of the underlying printed circuit board (PCB) to which the integrated processor is connected, while keeping the height reduced. However, the implementation of these thinner IC boards has caused warping problems to arise, which causes the IC devices to become non-planar. PCB warpage can cause undesirable defects to occur in the device, thereby affecting long-term IC performance.

In addition to achieving the above-mentioned thinner form factors, manufacturers must also be concerned with glass transition temperatures (Tg) of the circuit boards and achieving a good balance of thermal and mechanical properties in a wide process window. To this end, manufacturers have begun to lower the Tg slightly and enhance the resin component of multilayer printed circuits by lowering the CTE. The CTE is defined as the ratio of the change in length of a material per degree Celsius. Thermal expansion is important in design considerations, as it can dictate important parameters, such as the composite filler size and shape. In this manner, it is possible in the manufacture of multilayer circuit board to achieve a circuit board that is extremely reliable and cost effective in high volumes. Low CTE epoxies are currently being utilized extensively in a variety of IC board manufacturing programs. As the industry becomes less Tg oriented and more performance based, the use of low CTE epoxies has grown significantly with low CTE technology.

However, contrary to the general trend of the industry, the present disclosure recognizes that incorporation of a higher CTE material on the same surface as a lower CTE material provides improved coplanarity in thin IC carrier boards.

FIG. 1A generally illustrates one embodiment of an IC device 100 and FIG. 1B is a general schematic overhead view 105 of the IC device 100. In the illustrated embodiment, the IC device 100 comprises a printed circuit board (PCB) 110. The PCB 110 may be manufactured using conventional processes and materials, such as by liquid or film build-up processes and materials, such as an Ajinomoto Build-up Film (ABF) processes that use organic, epoxy-based resins containing a filler component, such as silicon, silicon dioxide, or micro-glass spheres, to achieve a desired parts per million (ppm)/particle concentration that affects the CTE of the film. As such, a desired CTE can be achieved by varying the amount of filler component during the formation of the film. When a lower CTE is required, a lower amount of filler will be used and when a higher CTE is required, the amount of filler can be increase.

It should be understood that the present disclosure is not limited to any particular organic epoxy-based, filled resin system. Such systems are well known to those skilled in the art of electronic board manufacturing processes and various epoxy filled resins may be selected as board design as specification requires . . . For example, it may be comprised of a layered organic epoxy resin core material having conductive interconnects 115 located between the layers of the PCB 110. The PCB 110 has a first material layer 120, which may be a solder mask material, such as an epoxy composite resin layer that may be formed by using conventional processes and materials. The first material layer 120 has a set of bond pads 125 located therein that form a contact array 130 defined by a perimeter 135. In certain applications, the contact array 130 can be used to connect an IC electrical component, such as a microprocessor to the PCB 110. The first material layer is an outer layer of the PCB 110 that is co-extensive with the perimeter, or footprint, of the PCB 110 and has a low coefficient of thermal expansion (CTE). For purposes of this disclosure and the claims, a low CTE material is one that has a CTE value that is less than 40 PPM/particle.

The embodiment of the IC device 100 illustrated in FIGS. 1A and 1B further comprises a second material layer 140 located at or adjacent an outer edge of the PCB 110. As seen in FIGS. 1A and 1b, the second material layer 140 is located outside the perimeter 130 of the contact array 135 at or adjacent the edge of the PCB 110. The second material layer 140 also has a higher CTE value and a greater thickness than the first material layer 120. As used herein and in the claims, a high CTE material is one that has a value that ranges from about 50 PPM/particle to about 200 PPM/particle. The thickness of the second material layer 140 may range from about 15 microns to about 50 microns.

The second material layer 140 may also be an organic epoxy resin material so that existing manufacturing equipment, processes and materials can be used to deposit or form and pattern the second material layer 140, where needed for certain applications. For example, the second material layer 140 can be a conventional solder mask material or build-up material, such as an Ajinomoto Build-up Film (ABF). However, a large amount of filler component is used during its fabrication to cause it to have a higher CTE than the first material layer 120. The embodiment illustrated in FIGS. 1A and 1B shows that the second material layer 140 is located on the first material layer at or adjacent the edges of the PCB 110. However, in other embodiments, the second material layer 140 may be located directly on the PCB 110.

In conventional configurations, manufacturers often have one or more layers having the same physical properties located at the upper most surface of the PCB. However, the present disclosure recognizes that the materials comprising these layers may be selected such that their CTE's and thicknesses, and in other embodiments Young's modulus of elasticity, may be selected such that they are different enough to inhibit or counteract the natural warping of the thinner PCB. By providing a material layer having a higher CTE and greater thickness, and in certain embodiments, a higher Young's modulus value, the second layer 140 provides an expansion or stress inducing force on the PCB 110 that is opposite to the material forces that causes warping. The opposing mechanical induces stresses present with the second material layer 140 inhibits or reduces the warping effects of the PCB 110.

In the illustrated embodiment of FIGS. 1A and 1B, the IC device 100 includes, in some embodiments, contact pads 115 located between a patterned region of the second material layer 140. This particular embodiment has application in POP configurations. However, it should be understood that in other embodiments that may not involve a POP application, the contact pads 115 are not present, and the second material layer 140 is not patterned at or adjacent the outer edge of the PCB 110.

In another aspect of this embodiment, the second material layer 140 also has a higher Young's modulus of elasticity than the first material layer 120, thereby causing it to be more rigid than the first material layer. In such embodiments, the Young's modulus of elasticity of the second material layer 140 may range from about 3 GPa to about 10 GPa. The higher Young's modulus provides a stiffer region at or adjacent the outer edges of the PCB 110, which further inhibits or reduces the warping of the thinner PCB 110.

FIG. 2A illustrates another embodiment an IC package 200 of the present disclosure. In this embodiment, the IC package 200 comprises the components discussed above with respect to the embodiments illustrated in FIG. 1. However, in addition, this embodiment further comprises an IC device 205, such as a microprocessor. The microprocessor is electrically connected to the contact grid array 130 by solder bumps 210 that contact the bond pads 125. This configuration is designed to have another IC electrical component, such as memory, electrically connected to electrical interconnects 115 located between the patterned second material layer 140 to form a POP IC device.

FIG. 2B shows another embodiment of an IC device 215 similar to the embodiment of FIG. 2A, except that the IC device 215 is not configured to be used in a POP device. As such, the second material layer 140 located at or adjacent the edge of the PCB 100 is not patterned.

FIG. 3 illustrates another embodiment where the IC device 200 is used in an IC POP device 300. In this embodiment, the IC POP device comprises the components (as indicated by the same reference numbers) of the IC device illustrated in FIG. 2A. In addition, however, the IC POP device 300 further comprises a packaged IC device 305 located over the IC device 200 and is electrically connected to the PCB 110 by conventional means, such as solder contacts 310 that contact the interconnects 115 that are located adjacent the second material layer 140. The packaged IC device 305 may be any type of conventional IC package, as required by the electronics device in which it is to be implemented. For example, the packaged IC device 305 may be a memory chip or a microprocessor.

Another embodiment is directed to a method of manufacturing the IC device of FIG. 1A and its various embodiments as discussed above. The method comprises forming a bond pad array on a printed circuit board (PCB), forming a first material layer over the bond pad array and forming bond pad openings therein to expose portions of the bond pad array to form a contact array having a perimeter, and forming a second material layer at or adjacent an outer edge of the PCB. The second material layer is located outside of the perimeter of the contact array and has a higher coefficient of thermal expansion (CTE) value and a greater thickness than the first material layer. It should be noted that conventional fabrication processes may be used to achieve the IC device illustrated in FIG. 1A.

Those skilled in the art to which this application relates will appreciate that other and further additions, deletions, substitutions and modifications may be made to the described embodiments.

What is claimed is:

1. An integrated circuit (IC) package, comprising:
a printed circuit board (PCB) having a first material layer located thereon, said first material layer having bond pads located therein that form a contact array defined by a perimeter; and
a second material layer located at or adjacent an outer edge of said PCB, said second material layer being located outside said perimeter of said contact array and having a higher coefficient of thermal expansion (CTE) value and a greater thickness than said first material layer.

2. The IC package of claim 1, wherein said CTE of said second material layer ranges from about 50 PPM/particle control to about 200 PPM/particle control.

3. The IC package of claim 1, wherein said second material layer has a higher modulus than said first material layer.

4. The IC package of claim 3, wherein said modulus ranges from about 3 GPa to about 10 GPa.

5. The IC package of claim 1, wherein said second material layer has bond pad openings located therein.

6. The IC package of claim 1, wherein said second material layer is located on said first material layer outside of said perimeter of said contact array.

7. The IC package of claim 1, wherein said second material layer has a thickness that ranges from about 15 microns to about 50 microns.

8. The IC package of claim 1, further comprising, an integrated processor electrically coupled to said PCB through said contact array.

9. An integrated circuit (IC) package on package (POP) device, comprising:
a printed circuit board (PCB) having a first material layer located thereon, said first material layer having bond pads located therein that form a contact array defined by a perimeter;
an integrated processor electrically coupled to said PCB through said contact array;
a second material layer located at or adjacent an outer edge of said PCB, said second material layer being located outside said perimeter of said contact array and having a higher coefficient of thermal expansion (CTE) value and a greater thickness than said first material layer, said second material layer having contact openings located therein at or adjacent said edge and outside said perimeter of said contact array; and
a packaged IC device located over said PCB and being electrically connected to said PCB by contacts located in said contact openings of said second material layer.

10. The IC POP device of claim 9, wherein said CTE of said second material layer ranges from about 50 PPM/particle control to about 200 PPM/particle control.

11. The IC POP device of claim 9, wherein said second material layer has a higher modulus than said first material layer.

12. The IC POP package of claim 11, wherein said modulus ranges from about 3 GPa to about 10 GPa.

13. The IC POP package of claim 9, wherein said packaged IC device is a memory package device.

14. The IC package of claim 9, wherein said second material layer is located on said first material layer outside of said contact grid array.

15. The IC package of claim 9, wherein said second material layer has a thickness that ranges from about 15 microns to about 50 microns.

16. A method of manufacturing an integrated circuit (IC) package, comprising:
forming a bond pad array on a printed circuit board (PCB);
forming a first material layer over said bond pad array and forming bond pad openings therein to expose portions of said body pad array to form a contact array having a perimeter; and
forming a second material layer at or adjacent an outer edge of said PCB, said second material layer being located outside of said perimeter of said contact array and having a higher coefficient of thermal expansion (CTE) value and a greater thickness than said first material layer.

17. The method of claim 16, wherein said CTE of said second material layer ranges from about 30 PPM/particle control to about 200 PPM/particle control and said thickness ranges from about 15 microns to about 50 microns.

18. The method of claim 16, wherein said second material layer has a higher modulus than said first material layer.

19. The method of claim 16, wherein said second material layer has bond pad openings located therein.

20. The method of claim 16, further comprising placing an integrated processor on said PCB and electrically coupling said integrated processor to said PCB through said contact array.
